(19) United States
(12) Patent Application Publication
(10) Pub. No.: US 2015/0188055 A1
(43) Pub. Date: Jul. 2, 2015

(54) ORGANIC ELECTROLUMINESCENT COMPOUND, ORGANIC ELECTROLUMINESCENT DIODE, AND METHOD OF PRODUCTION THEREOF

(71) Applicant: RESEARCH & BUSINESS FOUNDATION SUNGKYUNKWAN UNIVERSITY, Suwon-si (KR)

(72) Inventors: Seungsoo YOON, Seoul (KR); Hak Rim JEON, Suwon-si (KR); Ho Kyoon CHUNG, Suwon-si (KR); Hyejeong KIM, Gongju-si (KR)

(73) Assignee: RESEARCH & BUSINESS FOUNDATION SUNGKYUNKWAN UNIVERSITY, Suwon-si (KR)

(21) Appl. No.: 14/271,839

(22) Filed: May 7, 2014

(30) Foreign Application Priority Data
Dec. 31, 2013 (KR) 10-2013-0168634

(51) Int. Cl. H01L 51/00

(52) U.S. Cl. CPC H01L 51/0058; H01L 51/0054; H01L 51/005; H01L 51/5012

(57) ABSTRACT

An organic electroluminescent compound, an organic electroluminescent diode including an organic electroluminescent compound, and a method of producing an organic electroluminescent compound are provided.

### CROSS-REFERENCE TO RELATED APPLICATION

This application claims the benefit under 35 USC 119(a) of Korean Patent Application No. 10-2013-0168634 filed on Dec. 31, 2013, in the Korean Intellectual Property Office, the entire disclosure of which is incorporated herein by reference for all purposes.

### BACKGROUND

1. Field

The following description relates to an organic electroluminescent compound, an organic electroluminescent diode including the organic electroluminescent compound, and a method of producing the organic electroluminescent compound.

2. Description of Related Art

Recently, organic light-emitting diodes (OLEDs) are receiving a lot of attention due to their potential application in full-color, flat-panel display devices and spatial light modulators. In order to produce a full-color OLED for a display device or a spatial light modulator, a main light emitting device including red, green, and blue light emitting materials is used. Red light and green light emitting materials that exhibit high energy efficiency and saturation of color are available. However, available blue light emitting materials exhibit poor efficiency and color index. In order to reduce the power consumption by an OLED and to increase a range of color produced therefrom, it is desirable to develop a high-efficiency pure saturated-blue-light emitting material with a CIE_{y} (Commission Internationale de l'Eclairage y coordinate value) of 0.15 or less. However, a deep-blue-light emitting material with high efficiency, saturated color purity, and long operational lifetime due to a broad band gap of a blue material has not been achieved. Although many blue-light emitting materials such as pyrene (Hu, J.; Era, M.; Elsegood, M. R. J.; Yamato, T. Eur. J. Org. Chem. 2010, 72), anthracene (Lee, K. H.; Park, J. K.; Seo, J. H.; Park, S. W.; Kim, Y. S.; Kim, Y. K.; Yoon, S. S. J Mater. Chem. 2011, 21, 13640), fluorene (Kwon, Y. S.; Lee, K. H.; Kim, G. Y.; Seo, J. H.; Kim, Y. K.; Yoon, S. S. J. Nanosci. Nanotechnol. 2009, 9, 7056), aromatics (Lee, K. H.; Kwon, Y. S.; Lee, J. Y.; Kang, S.; Yook, K. S.; Jeon, S. O.; Lee, J. Y.; Yoon, S. S. Chem. Eur. J. 2011, 17, 12994), and triarylamine (Lee, K. H.; Kang, S.; Lee, J. Y.; Jeon, S. O.; Yook, K. S.; Lee, J. Y.; Yoon, S. S. Adv. Funct. Mater. 2010, 20, 1345) are known, electroluminescence (EL) efficiency of such a deep-blue OLED is much lower than a sky-blue OLED. Therefore, the development of a new efficient deep-blue fluorescent material with high performance is desirable in order to realize the use of OLEDs for various applications.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided a compound of Formula (1):

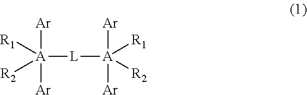

wherein A comprises a five-membered unsaturated or aromatic ring, a six-membered unsaturated or aromatic ring, a five-membered unsaturated or aromatic hetero ring, or a six-membered unsaturated or aromatic hetero ring;

either R₁ and R₂ each independently comprise a five-membered unsaturated or aromatic ring, a six-membered unsaturated or aromatic ring, a five-membered unsaturated or aromatic hetero ring, or a six-membered unsaturated or aromatic hetero ring, or

R₁ and R₂ are fused to form a polycyclic fused ring of at least two rings that are selected from the group consisting of a five-membered unsaturated or aromatic ring comprising at least one of C₆-C₂₀ fused rings, a six-membered unsaturated or aromatic ring comprising at least one of C₆-C₂₀ fused rings, a five-membered unsaturated or aromatic hetero ring comprising at least one of C₆-C₂₀ fused rings, and a six-membered unsaturated or aromatic hetero ring comprising at least one of C₆-C₂₀ fused rings;

Ar comprises a member selected from the group consisting of phenyl, biphenyl, naphthyl, dibenzothiophenyl, dibenzofuranyl, terphenyl, stilbene group, anthracenyl, pyrenyl, and perylenyl; and

L comprises a member selected from the group consisting of a five-membered unsaturated or aromatic ring that is substituted with phenyl, naphthyl, biphenyl, terphenyl, stilbene group, anthracenyl, phenanthrenyl, pyrenyl, or perylenyl; a six-membered unsaturated or aromatic ring that is substituted with phenyl, naphthyl, biphenyl, terphenyl, stilbene group, anthracenyl, phenanthrenyl, pyrenyl, or perylenyl; a five-membered unsaturated or aromatic hetero ring that is substituted with phenyl, naphthyl, biphenyl, terphenyl, stilbene group, anthracenyl, phenanthrenyl, pyrenyl, or perylenyl; and a six-membered unsaturated or aromatic hetero ring that is substituted with phenyl, naphthyl, biphenyl, terphenyl, stilbene group, anthracenyl, phenanthrenyl, pyrenyl, or perylenyl; or a polycyclic ring formed by fusion of at least two rings selected from the group above.

The compound may be represented by one of Formulas (2), (3) and (4):

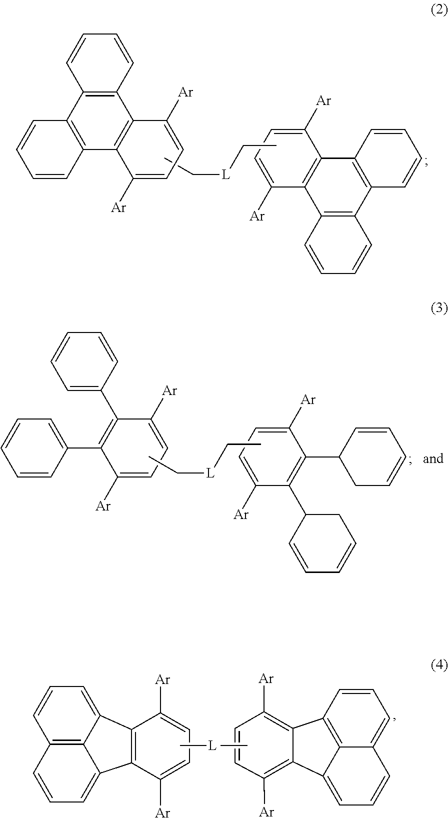

wherein Ar and L are as defined above.

L may be a substituent selected from the following:

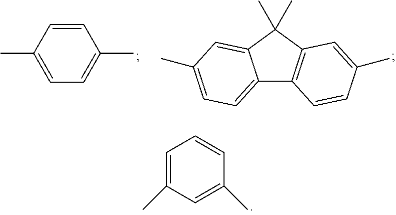

The compound of Formula (1) may have a maximum emission peak in a range of approximately 440 nm to 465 nm.

In another general aspect, a method of producing the compound involves: reacting a compound represented by Formula (5) with a compound represented by Formula (6) in presence of an organic solvent:

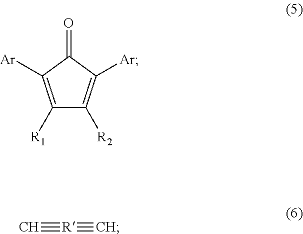

wherein either R₁ and R₂ each independently comprise a five-membered unsaturated or aromatic ring, a six-membered unsaturated or aromatic ring, a five-membered unsaturated or aromatic hetero ring, or a six-membered unsaturated or aromatic hetero ring, or

R₁ and R₂ are fused to form a polycyclic fused ring of at least two rings that are selected from the group consisting of a five-membered unsaturated or aromatic ring comprising at least one of C₆-C₂₀ fused rings; a six-membered unsaturated or aromatic ring comprising at least one of C₆-C₂₀ fused rings; a five-membered unsaturated or aromatic hetero ring comprising at least one of C₆-C₂₀ fused rings; and a six-membered unsaturated or aromatic hetero ring comprising at least one of C₆-C₂₀ fused rings; and

Ar comprises a member selected from the group consisting of phenyl, naphthyl, biphenyl, terphenyl, stilbene group, anthracenyl, phenanthrenyl, pyrenyl, and perylenyl, and

R′ comprises a member selected from the group consisting of a five-membered unsaturated or aromatic ring that is substituted with an C₁-C₈ alkyl group; a six-membered unsaturated or aromatic ring that is substituted with an C₁-C₈ alkyl group; a five-membered unsaturated or aromatic hetero ring that is substituted with an C₁-C₈ alkyl group; and a six-membered unsaturated or aromatic hetero ring that is substituted with an C₁-C₈ alkyl group; or a polycyclic ring formed by fusion of at least two rings selected from the group above.

The reacting may be performed at a temperature in a range of from about 100° C. to about 300° C.

The compound represented by Formula (5) may be represented by one of Formulas (7), (8) and (9):

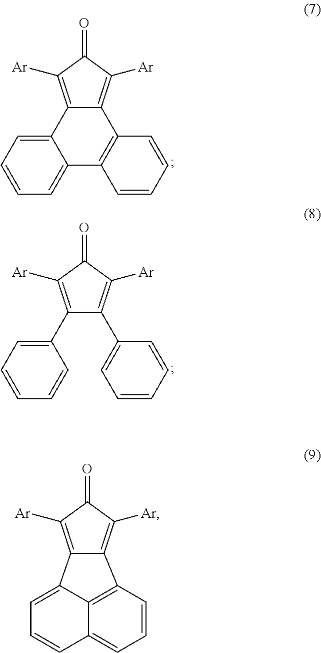

wherein Ar is the same as defined in claim 4.

The compound represented by Formula (6) may include a member selected from the following:

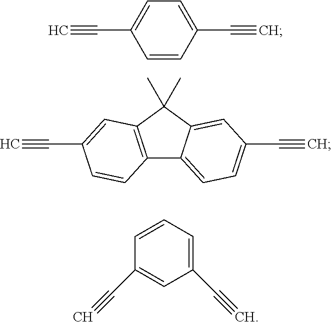

In another general aspect, there is provided an organic electroluminescent diode comprising an anode, a cathode, and an organic layer including the compound of Formula (1) described above.

Other features and aspects will be apparent from the following detailed description, the drawings, and the claims.

### BRIEF DESCRIPTION OF THE DRAWINGS

FIGS. 1A to 1C respectively illustrate a UV absorption spectra (FIG. 1A), a PL spectra at CH₂Cl₂ (FIG. 1B), and a solid PL spectra at a thin film (FIG. 1C) of examples of organic electroluminescent compounds in accordance with the present disclosure.

FIGS. 2A to 2C respectively illustrate a UV absorption spectra (FIG. 2A), a PL spectra (FIG. 2B), and a solid PL spectra (FIG. 2C) of additional examples of organic electroluminescent compounds in accordance with the present disclosure.

FIG. 3 illustrates a schematic view of an example of a device that includes an organic electroluminescent compound and a graph illustrating an energy level thereof.

FIG. 4 illustrates normalized an EL spectra of an example of a device that includes examples of organic electroluminescent compounds in accordance with the present disclosure.

FIGS. 5A to 5C respectively illustrate a J-V-L graph (FIG. 5A), a luminance efficiency and power efficiency graph (FIG. 5B), and an external quantum efficiency graph (FIG. 5C) with respect to a current density of a device including organic electroluminescent compounds in accordance with the present disclosure.

FIGS. 6A and 6B illustrate graphs respectively showing a current density (FIG. 6A) and a luminescent property (FIG. 6B) depending on a voltage of a device including examples of organic electroluminescent compounds in accordance with the present disclosure.

FIG. 7A to FIG. 7C illustrate graphs respectively showing an EL spectra (FIG. 7A), and a luminance efficiency (FIG. 7B) and a power efficiency (FIG. 7C) with respect to a current density of a device including examples of organic electroluminescent compounds in accordance with the present disclosure.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the systems, apparatuses and/or methods described herein will be apparent to one of ordinary skill in the art. The progression of processing steps and/or operations described is an example; however, the sequence of and/or operations is not limited to that set forth herein and may be changed as is known in the art, with the exception of steps and/or operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless indicated otherwise, a statement that a first element is “on” a second element or a layer is to be interpreted as covering both a case where the first element directly contacts the second element or the layer, and a case where one or more other elements are disposed between the first element and the second element or the layer.

The spatially-relative expressions such as “below”, “beneath”, “lower”, “above”, “upper”, and the like may be used to conveniently describe relationships of one device or elements with other devices or among elements. The spatially-relative expressions should be understood as encompassing the direction illustrated in the drawings, added with other directions of the device in use or operation. Further, the device may be oriented to other directions and accordingly, the interpretation of the spatially-relative expressions is based on the orientation.

The term “comprises or includes” and/or “comprising or including” means that one or more other components, steps, operation and/or existence or addition of elements are not excluded in addition to the described components, steps, operation and/or elements unless context dictates otherwise. The term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party. The term “step of” does not mean “step for”.

The term “combination(s) of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Throughout the present disclosure, a phrase in the form “A and/or B” means “A, B, or A and B”.

The term “alkyl group” refers to a linear or branched C₁₋₃₀, C₁₋₂₀, C₁₋₁₀, or C₁₋₈ alkyl group, and may include, for example, but not limited to, methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl, eicosyl, heneicosyl, docosyl, tricosyl, tetracosyl, pentacosyl, hexacosyl, heptacosyl, octacosyl, nonacosyl, triacontyl, or all available isomers thereof.

The term “aryl group (Ar)” means a monovalent functional group formed by removing hydrogen atoms present at one or more rings of arene and refers to a C₆₋₂₀ aryl group, and may include, for example, but not limited to, phenyl, biphenyl, terphenyl, naphthyl, anthryl, phenanthryl, pyrenyl, dibenzothiophenyl, dibenzofuranyl, stilbenyl, anthracenyl, perylenyl, or all available isomers thereof. The arene refers to a hydrocarbon group having an aromatic ring and includes a monocyclic or polycyclic hydrocarbon group, and the polycyclic hydrocarbon group includes at least one of aromatic rings and may include an aromatic ring or a non-aromatic ring as an additional ring, but the present disclosure may not be limited thereto.

The term “aromatic ring” refers to an aromatic ring including a C₆₋₃₀ aromatic hydrocarbon ring group, for example, phenyl, naphthyl, biphenyl, terphenyl, fluorene, phenanthrenyl, triphenylenyl, perylenyl, chrysenyl, fluoranthenyl, benzofluorenyl, benzotriphenylenyl, benzochrysenyl, anthracenyl, stilbene group, pyrenyl, etc., and the term “aromatic hetero ring” refers to an aromatic ring including at least one hetero material and may include, for example, pyrrolyl, pyrazinyl, pyridinyl, indolyl, isoindolyl, furyl, benzofuranyl, isobenzofuranyl, dibenzofuranyl, dibenzothiophenyl, a quinolyl group, isoquinolyl, quinoxalinyl, carbazolyl, phenanthridinyl, acridinyl, phenanthrolinyl, thienyl, and an aromatic hetero ring group formed of, a pyridine ring, a pyrazine ring, a pyrimidine ring, a pyridazine ring, a triazine ring, an indole ring, a quinoline ring, an acridine ring, a pyrrolidine ring, a dioxane ring, a piperidine ring, a morpholine ring, a piperazine ring, a carbazole ring, a furan ring, a thiophene ring, an oxazole ring, an oxadiazole ring, a benzoxazole ring, a thiazole ring, a thiadiazole ring, a benzothiazole ring, a triazole ring, an imidazole ring, a benzoimidazole ring, a pyran ring, and a dibenzofuran ring.

The term “fusion” means that with respect to two or more rings, at least one pair of adjacent atoms is included in two rings.

The term “fused ring” means that at least one of C₆₋₂₀ aromatic rings or unsaturated hydrocarbon rings are fused.

An example according to the present disclosure relates to a novel organic electroluminescent compound that has high luminance, luminance efficiency, power efficiency, and prominent electroluminescence (EL) performance of external quantum efficiency, which can thus be used as a blue light emitting material for a high-efficiency OLED.

Hereinafter, various example embodiments of the present disclosure will be explained in detail with reference to the accompanying drawings. However, the present disclosure may not be limited thereto.

In a first aspect of the present disclosure, there is provided an organic electroluminescent compound represented by the following Chemical Formula 1:

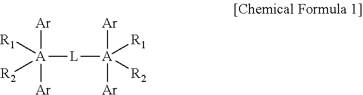

wherein

A includes a five-membered unsaturated or aromatic ring, a six-membered unsaturated or aromatic ring, a five-membered unsaturated or aromatic hetero ring, or a six-membered unsaturated or aromatic hetero ring;

each of R₁ and R₂ either independently includes a five-membered unsaturated or aromatic ring, a six-membered unsaturated or aromatic ring, a five-membered unsaturated or aromatic hetero ring, or a six-membered unsaturated or aromatic hetero ring, or R₁ and R₂ are fused to form a polycyclic fused ring of at least two rings which are selected from the group consisting of a five-membered unsaturated or aromatic ring including at least one of C₆-C₂₀ fused rings; a six-membered unsaturated or aromatic ring including at least one of C₆-C₂₀ fused rings; a five-membered unsaturated or aromatic hetero ring including at least one of C₆-C₂₀ fused rings; and a six-membered unsaturated or aromatic hetero ring including at least one of C₆-C₂₀ fused rings;

Ar includes a member selected from the group consisting of phenyl, biphenyl, naphthyl, dibenzothiophenyl, dibenzofuranyl, terphenyl, stilbene group, anthracenyl, pyrenyl, and perylenyl; and

L includes a member selected from the group consisting of a five-membered unsaturated or aromatic ring which may be substituted with phenyl, naphthyl, biphenyl, terphenyl, stilbene group, anthracenyl, phenanthrenyl, pyrenyl, or perylenyl; a six-membered unsaturated or aromatic ring which may be substituted with phenyl, naphthyl, biphenyl, terphenyl, stilbene group, anthracenyl, phenanthrenyl, pyrenyl, or perylenyl; a five-membered unsaturated or aromatic hetero ring which may be substituted with phenyl, naphthyl, biphenyl, terphenyl, stilbene group, anthracenyl, phenanthrenyl, pyrenyl, or perylenyl; and a six-membered unsaturated or aromatic hetero ring which may be substituted with phenyl, naphthyl, biphenyl, terphenyl, stilbene group, anthracenyl, phenanthrenyl, pyrenyl, or perylenyl; or a polycyclic ring formed by fusion of at least two rings selected from the group above.

In accordance with an example embodiment of the present disclosure, the organic electroluminescent compound may include, but may not be limited to, any one of compounds represented by the following Chemical Formulas 2 to 4:

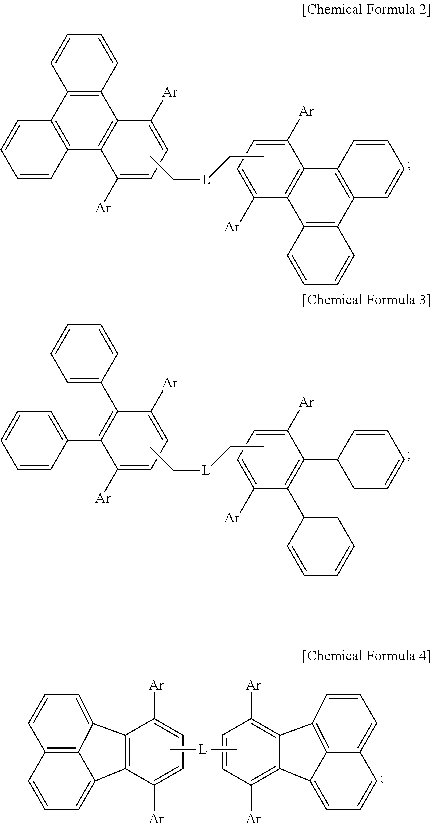

wherein each of Ar and L is the same as defined above.

In accordance with an example embodiment of the present disclosure, L is selected from the following substituents:

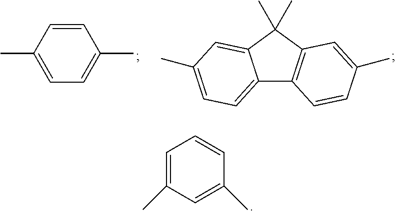

However, the present disclosure is not limited thereto.

In accordance with an example embodiment of the present disclosure, the organic electroluminescent compound of the present disclosure may include the following compounds:

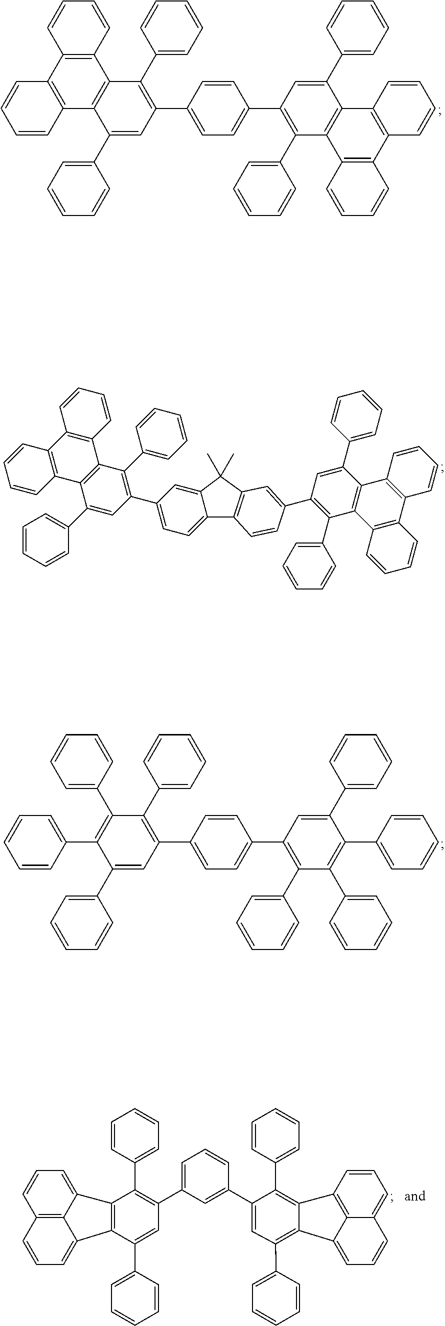

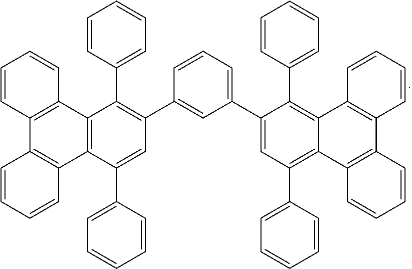 [SMILES: c1ccc(-c2cc(-c3cccc(-c4cc(-c5ccccc5)c5c6ccccc6c6ccccc6c5c4-c4ccccc4)c3)c(-c3ccccc3)c3c4ccccc4c4ccccc4c23)cc1]

However, the present disclosure is not limited thereto.

In a second aspect of the present disclosure, there is provided an example a method of producing the organic electroluminescent compound, the method involving: reacting a compound represented by the following Chemical Formula 5 with a compound represented by the following Chemical Formula 6 in the presence of an organic solvent:

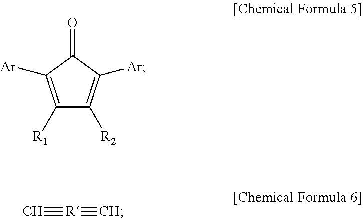

in Chemical Formula 5 and Chemical Formula 6,
each of R₁ and R₂ independently includes a five-membered unsaturated or aromatic ring, a six-membered unsaturated or aromatic ring, a five-membered unsaturated or aromatic hetero ring, or a six-membered unsaturated or aromatic hetero ring, or R₁ and R₂ are fused to form a polycyclic fused ring of at least two rings which are selected from the group consisting of a five-membered unsaturated or aromatic ring including at least one of C₆-C₂₀ fused rings; a six-membered unsaturated or aromatic ring including at least one of C₆-C₂₀ fused rings; a five-membered unsaturated or aromatic hetero ring including at least one of C₆-C₂₀ fused rings; and a six-membered unsaturated or aromatic hetero ring including at least one of C₆-C₂₀ fused rings,
Ar includes a member selected from the group consisting of phenyl, naphthyl, biphenyl, terphenyl, stilbene group, anthracenyl, phenanthrenyl, pyrenyl, and perylenyl, and R′ includes a member selected from the group consisting of a five-membered unsaturated or aromatic ring which may be substituted with an C₁-C₈ alkyl group; a six-membered unsaturated or aromatic ring which may be substituted with an C₁-C₈ alkyl group; a five-membered unsaturated or aromatic hetero ring which may be substituted with an C₁-C₈ alkyl group; and a six-membered unsaturated or aromatic hetero ring which may be substituted with an C₁-C₈ alkyl group; or a polycyclic ring formed by fusion of at least two rings selected from the group above.

The organic solvent in accordance with the present disclosure may include, for example, trimethylbenzene or xylene. However, the present disclosure is not limited thereto.

In accordance with an example embodiment of the present disclosure, the organic electroluminescent compound may be produced by an aldol condensation reaction followed by a Diels-Alder reaction. However, the method of producing the compound is not limited thereto.

In accordance with an example embodiment of the present disclosure, the reaction is performed at a temperature in a range of from about 100° C. to about 300° C., from about 150° C. to about 300° C., from about 200° C. to about 300° C., from about 100° C. to about 250° C., from about 100° C. to about 200° C., or from about 100° C. to about 150° C. However, the present disclosure is not limited thereto.

In accordance with an example embodiment of the present disclosure, the compound represented by Chemical Formula 5 above may include, but may not be limited to, any one of compound of the following Chemical Formulas 7 to 9:

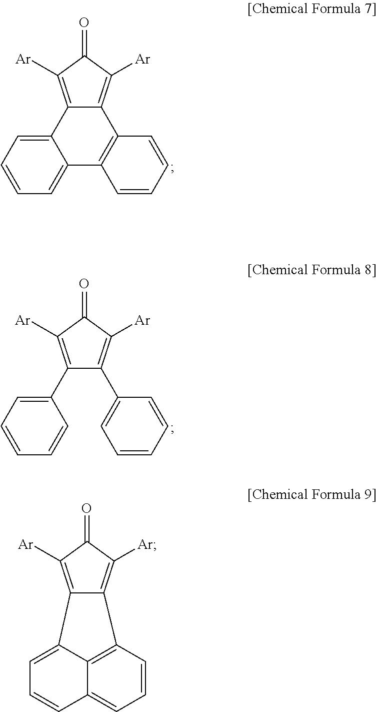

wherein Ar is the same as defined above.

In accordance with an example embodiment of the present disclosure, the compound represented by Chemical Formula 6 above may include, but may not be limited to, a member selected from the following compounds:

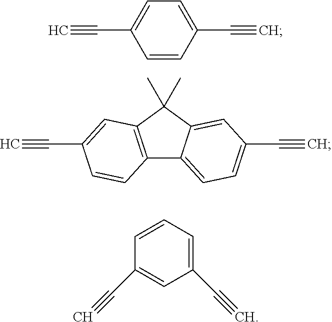

In accordance with an example embodiment of the present disclosure, examples of a reaction formula of the producing method of the organic electroluminescent compound may include, but may not be limited to, the following reaction formulas:

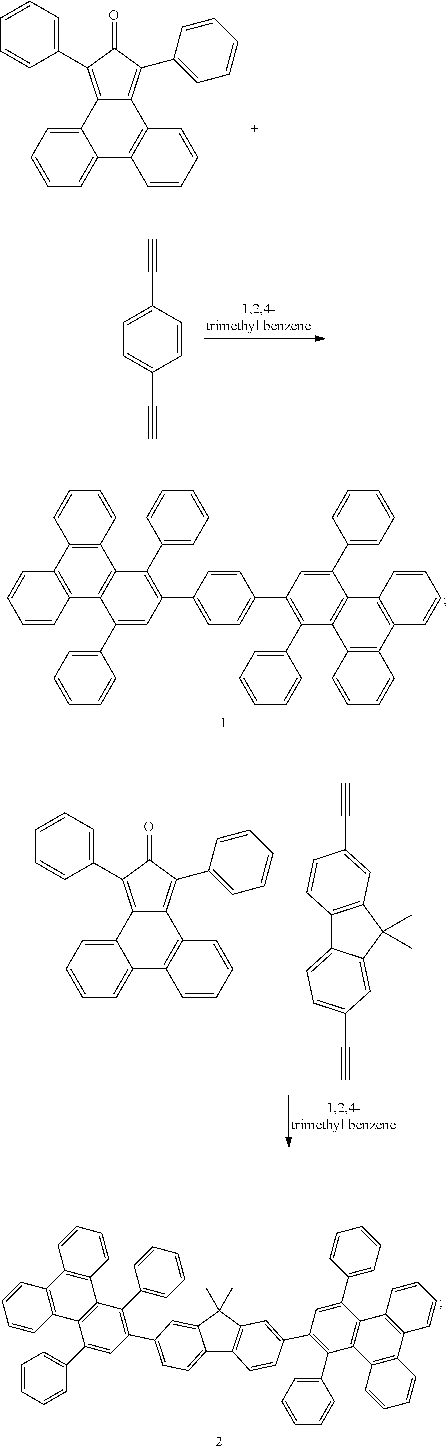

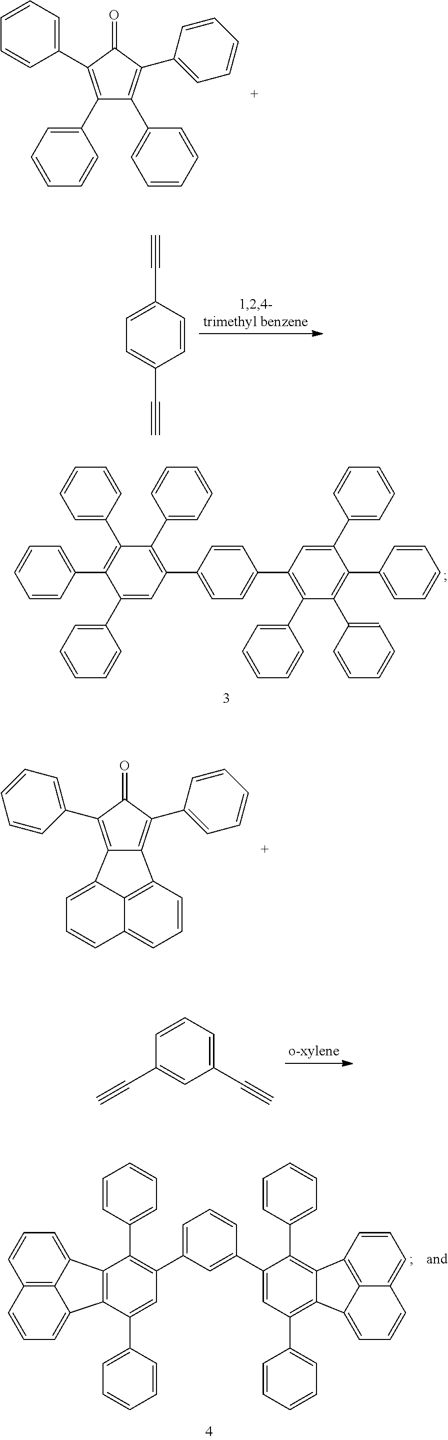

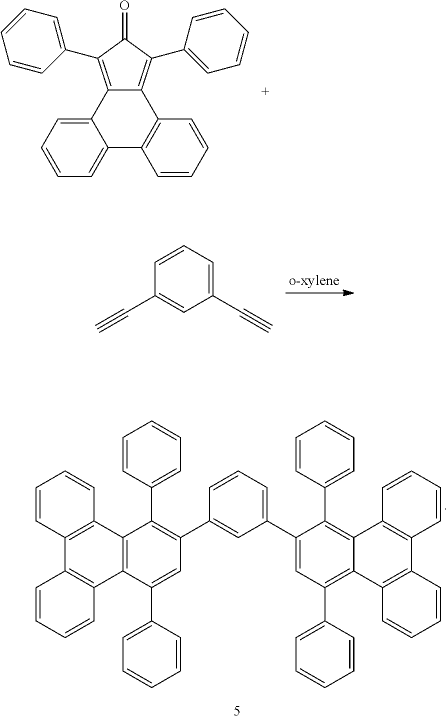

In a third aspect of the present disclosure, there is provided an organic electroluminescent diode comprising: an anode, a cathode, and an organic layer including the organic electroluminescent compound according to the present disclosure. All of the descriptions about the first aspect and the second aspect can be applied to the organic electroluminescent compound in accordance with the present aspect, but may not be limited thereto.

Hereinafter, a number of examples of the present disclosure will be explained in detail. However, the present examples do not limit the scope of the present disclosure.

### EXAMPLE

All solvents other than the solvents mentioned herein were dried in accordance with the standard procedure, and all reactants were used as provided. All reactions were carried out under a N₂ atmosphere.

³H and ¹³C NMR (nuclear magnetic resonance) spectra were recorded with the use of a Varian (Unity Inova 300 Nb or Unity (nova 500 Nb) spectrometer. FT-IR (Fourier transform infrared) spectra were recorded with the use of a Bruker VERTEX70 FT-IR. Elemental analysis (EA) was performed with the use of an EA 1108 spectrometer.

### Example 1

### Production of 1,4-bis(1,4-diphenyltriphenylene-2-yl)benzene

A 25 mL solution of 1,2,4-trimethylbenzene was added to a mixture of phencyclone (1.0 g, 1.25 mmol) and 1,4-diethynylbenzene (0.15 g, 1.19 mmol) in a flask, and heated under reflux at 180° C. for 48 hours. The reaction mixture was filtered with ethanol. A crude solid dissolved in toluene was filtered, and evaporated under reduced pressure. A resultant crude product was recrystallized from tetrahydrofuran/ethanol. An analysis result of Example 1 was as follows.

### 1,4-bis(1,4-diphenyltriphenylene-2-yl)benzene (1)

(69% yield); 1H NMR (300 MHz, CDCl₃) δ8.42 (d, J=8.1 Hz, 4H), 7.70 (d, J=8.4 Hz, 2H), 7.64 (s, 2H), 7.54-7.50 (m, 6H), 7.46-7.34 (m, 12H), 7.14-6.99 (m, 12H), 6.90 (s, 4H); FT-IR [ATR]: v=3060, 3018, 1441, 845, 730, 695 cm⁻¹; Elemental analysis. Calculated values C₆₆H₄₂: C, 94.93; H, 5.07; Measured values: C, 94.67; H, 5.33.

### Example 2

### Production of 2,2′-(9,9-dimethyl-9H-fluorene-2,7-diyl)bis(1,4-diphenyltriphenylene)

A 25 mL solution of 1,2,4-trimethylbenzene was added to a mixture of phencyclone (1.0 g, 1.25 mmol) and 2,7-diethynyl-9,9-dimethyl-9H-fluorene (0.29 g, 1.19 mmol) in a flask, and heated under reflux at 180° C. for 48 hours. The reaction mixture was filtered with ethanol. A crude solid dissolved in toluene was filtered, and evaporated under reduced pressure. A resultant crude product was recrystallized from tetrahydrofuran/ethanol. An analysis result of Example 2 was as follows.

### 2,2′-(9,9-dimethyl-9H-fluorene-2,7-diyl)bis(1,4-diphenyltriphenylene) (2)

(71% yield); ¹H NMR (300 MHz, CDCl₃) 58.44 (d, J=7.8 Hz, 4H), 7.76 (s, 2H), 7.72 (d, J=8.4 Hz, 2H), 7.64-7.53 (m, 8H), 7.47-7.39 (m, 10H), 7.32 (d, J=9.6 Hz, 2H), 7.16-7.10 (m, 12H), 7.02 (t, J=7.5 Hz, 2H), 6.76 (s, 2H), 0.92 (s, 6H); FT-IR [ATR]: v=3057, 3031, 2957, 2922, 2856, 1467, 1441, 825, 762, 701 cm⁻¹; Elemental analysis. Calculated values C₇₅H₅₀: C, 94.70; H, 5.30; Measured values: C, 94.60; H, 5.40.

### Example 3

### Production of 1,4-bis(2′,3′,4′,5′-tetraphenylbenzene-1-yl)benzene

A 25 mL solution of 1,2,4-trimethylbenzene was added to a mixture of 2,3,4,5-tetraphenylcyclopenta-2,4-dienone (0.48 g, 1.25 mmol) and 1,4-diethynylbenzene (0.15 g, 1.19 mmol) in a flask, and heated under reflux at 180° C. for 48 hours. The reaction mixture was filtered with ethanol. A crude solid dissolved in toluene was filtered, and evaporated under reduced pressure. A resultant crude product was recrystallized from tetrahydrofuran/ethanol. An analysis result of Example 3 was as follows.

### 1,4-bis(2′,3′,4′,5′-tetraphenylbenzene-1-yl)benzene (3)

(65% yield); ¹H NMR (300 MHz, CDCl₃) δ 7.54 (s, 2H), 7.14 (s, 8H), 6.93-6.90 (m, 14H), 6.86-6.75 (m, 22H); FT-IR [ATR]: v=3055, 3022, 2937, 2865, 1599, 1440, 1071, 843, 759, 697 cm⁻¹; Elemental analysis. Calculated values C₆₆H₄₆: C, 94.34; H, 5.66; Measured values: C, 94.67; H, 5.33.

### Example 4

### Production of 1,3-bis(7,10-diphenylfluoranthene-8-yl)benzene

A 25 mL solution of Xylene was added to a mixture of 7,9-diphenyl-8H-cyclopenta acenaphthalene-8-one (0.44 g, 1.25 mmol) and 1,3-diethynylbenzene (0.24 g, 1.19 mmol) in a flask, and heated under reflux at 180° C. for 48 hours. The reaction mixture was filtered with ethanol. A crude solid dissolved in toluene was filtered, and evaporated under reduced pressure. A resultant crude product was recrystallized from tetrahydrofuran/ethanol. An analysis result of Example 4 was as follows.

### 1,3-bis(7,10-diphenylfluoranthene-8-yl)benzene (4)

(85% yield); ¹H NMR (300 MHz, CDCl₃) δ 7.73-7.67 (m, 10H), 7.58-7.52 (m, 10H), 7.35-7.18 (m, 10H), 7.04 (s, 2H), 6.96 (m, 4H), 6.69 (d, J=6.9 Hz, 2H); FT-IR: v=2957, 2853, 1740, 1215, 1087 cm⁻¹.

### Example 5

### Production of 1,3-bis(1,4-diphenyltriphenylene-2-yl)benzene

A 25 mL solution of Xylene was added to a mixture of 1,3-diphenyl-2H-cyclopenta phenanthrene-2-one (0.48 g, 1.25 mmol) and 1,3-diethynylbenzene (0.24 g, 1.19 mmol) in a flask, and heated under reflux at 180° C. for 48 hours. The reaction mixture was filtered with ethanol. A crude solid dissolved in toluene was filtered, and evaporated under reduced pressure. A resultant crude product was recrystallized from tetrahydrofuran/ethanol. An analysis result of Example 5 was as follows.

### 1,3-bis(1,4-diphenyltriphenylene-2-yl)benzene (5)

(50% yield); ¹H NMR (300 MHz, CDCl₃) δ 8.40 (d, J=7.8 Hz), 6.79-7.71 (m, 38H); FT-IR: v=3188, 2712, 1086, 969 cm⁻¹.

### Experimental Example 1

### Photophysical Characteristic Measurement

The UV-Vis absorption (ultraviolet-visible spectroscopy) measurements of the produced compounds in dichloromethane (10⁻⁵ M) were acquired with a Sinco S-3100 in a quartz cuvette (1.0 cm path). Photoluminescence spectra were measured with an Amincobrowman series 2 luminescence spectrometer. The fluorescence quantum yields of the blue materials were measured in dichloromethane at 293 K with respect to DPA (Φ=0.90) as a reference material.

HOMO (highest occupied molecular orbital) energy levels were measured with a low energy photoelectron spectrometer (Riken-Keiki, AC-2).

The energy band gaps were determined from the intersection of the absorption and photoluminescence (PL) spectra. LUMO (lowest unoccupied molecular orbital) energy levels were calculated by subtracting the corresponding optical band gap energies from the HOMO energy values.

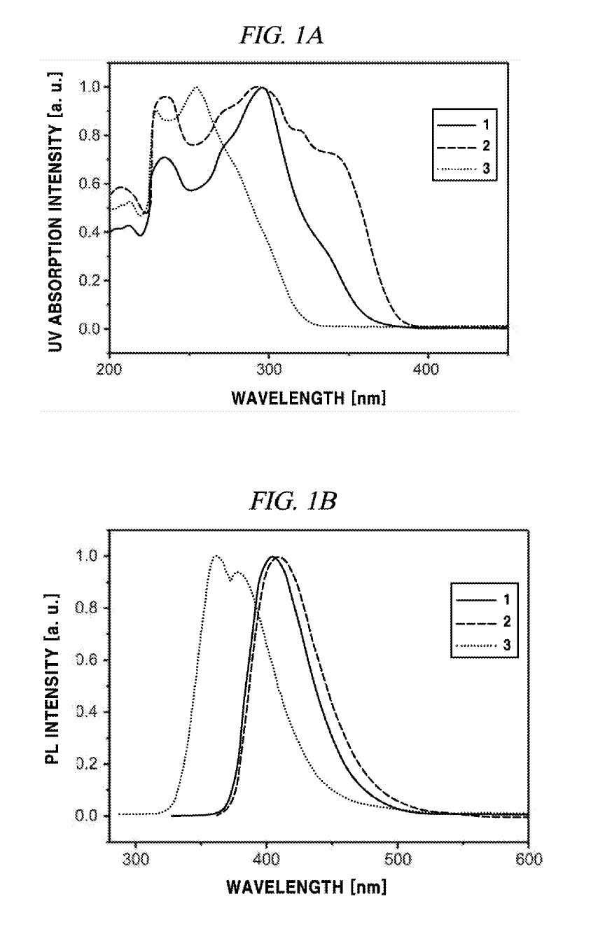

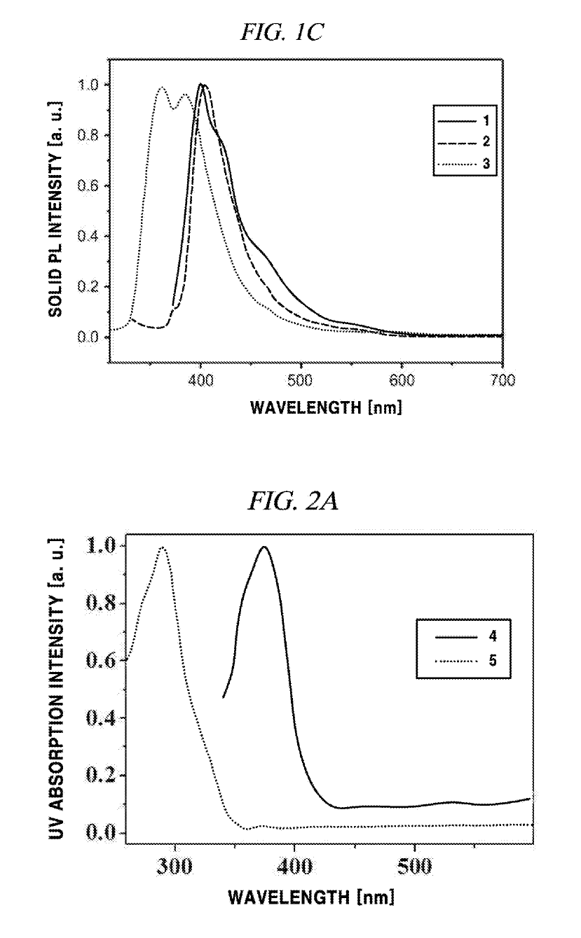

Among the compounds of Examples, absorption and emission spectra of the blue materials 1 to 3 were as shown in FIG. 1A to FIG. 1C, and analysis data of their photophysical properties were as shown in Table 1.

TABLE 1
Photophysical data of triphenylene derivatives 1 to 3

| Com- | UVₘₐₓ^{a} | PLₘₐₓ^{a,b} | FWHM | | | | |
|---|---|---|---|---|---|---|---|
| pound | [nm] | [nm] | [nm] | HOMO^{e} | LUMO^{e} | Eg^{d} | Φ^{c} |
| 1 | 294 | 406/400 | 52 | 6.01 | 2.64 | 3.37 | 0.13 |
| 2 | 295 | 410/406 | 58 | 6.00 | 2.71 | 3.29 | 0.33 |
| 3 | 254 | 360/361 | 61 | 6.11 | 2.31 | 3.80 | 0.76 |

HOMO levels were measured with a photoelectron spectrometer (Riken-Keiki, AC-2), and LUMO levels were calculated by subtracting the corresponding optical band gap energies from the HOMO values. HOMO energy levels of the materials 1 to 3 were measured as −6.01 eV, −6.00 eV, and −6.11 eV, respectively. Optical energy band gaps (Eg) of the materials were 3.37 eV, 3.29 eV, and 3.80 eV, respectively, as measured at the absorption spectra.

LUMO levels of the materials 1 to 3 were calculated as −2.64 eV, −2.71 eV, and −2.31 eV, respectively, by subtracting the corresponding optical band gap energies from the HOMO values.

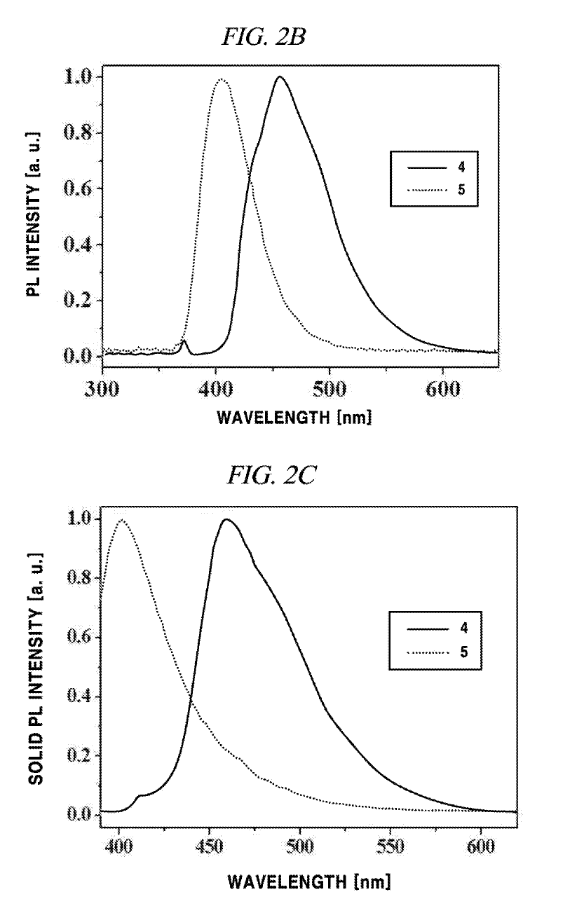

UV absorption spectra and PL intensities of the produced blue materials 4 and 5 were as shown in FIG. 2A to FIG. 2C.

### Example 6

### Fabrication and Measurement of Devices 1 to 3

For fabrication of an OLED, a glass substrate coated with an indium-tin-oxide (ITO) thin film was used. The glass substrate had a sheet resistance of 12 Ω/square and a thickness of 1000 Å. The ITO-coated glass was washed in an ultrasonic bath by the following sequence: acetone, methyl alcohol, and distilled water, followed by storage in isopropyl alcohol for 20 min and drying with a N₂ gas gun. The substrate was treated with O₂ plasma under an Ar atmosphere. Organic layers were deposited by thermal evaporation from resistively heated alumina crucibles onto the substrate at a rate of 1.0 Å/s. All organic materials and metal were deposited under a high vacuum (5.0×10⁻⁷ Torr). The OLED in accordance with the present disclosure was fabricated in the following sequence: ITO/4,4′-bis(N-(1-naphthyl)-N-phenylamino)-biphenyl (NPB, HTL) (50 nm)/Blue materials 1-3 (30 nm)/4,7-diphenyl-1,10-phenanthroline (Bphen, ETL) (30 nm)/lithium quinolate (Liq) (1.0 nm)/Al (100 nm). Current-voltage-luminance (J-V-L) characteristics and electroluminescence (EL) spectra of the device were measured with a Keithley 2400 source measurement unit and CS 1000A spectrophotometer.

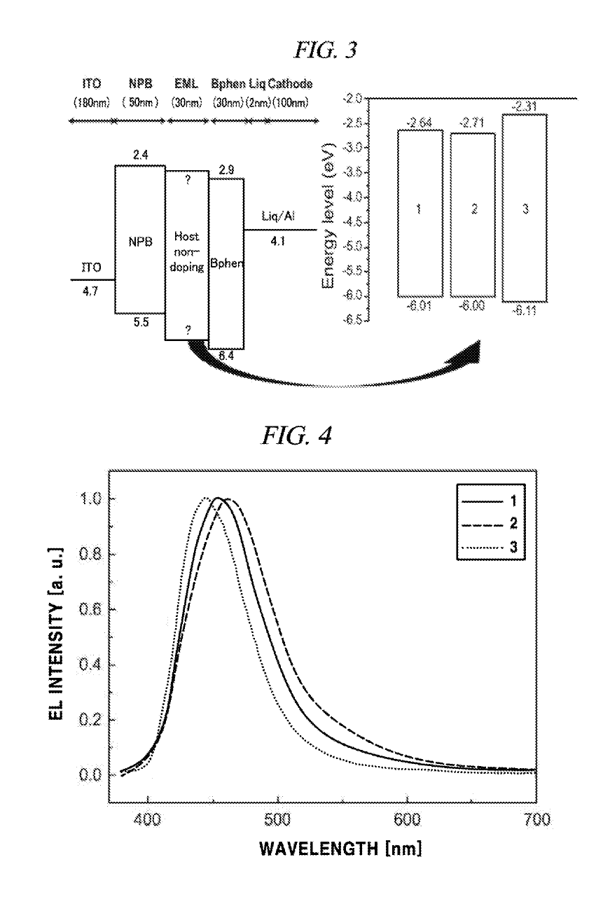

FIG. 3 illustrates a structure of the device according to Example 6, and HOMO and LUMO energy levels of blue fluorescent materials 1 to 3 used together with other materials in an OLED device.

The device fabricated to have a structure illustrated in FIG. 3 has the following arrangement: ITO/4,4′-bis(N-(1-naphthyl)-N-phenylamino)biphenyl (NPB) (50 nm)/blue materials 1-3 (30 nm)/4,7-diphenyl-1,10-phenanthroline (Bphen) (30 nm)/lithium quinolate (Liq) (2.0 nm)/AI (100 nm). The performance characteristics of the device are provided in Table 2

TABLE 2
Performance characteristic of devices 1 to 3

| | ELₘₐₓ | L | LE | PE | EQE | CIE |
|---|---|---|---|---|---|---|
| Device | [nm] | [cd/m²]^{a} | [cd/A]^{b/c} | [lm/W]^{b/c} | [%]^{b/c} | (x, y)^{d} |
| 1 | 455 | 978 | 0.86/0.80 | 0.52/0.34 | 0.74/0.73 | (0.17, |
| | | | | | | 0.14) |
| 2 | 462 | 430 | 0.75/0.63 | 0.43/0.23 | 0.55/0.48 | (0.17, |
| | | | | | | 0.17) |
| 3 | 445 | 265 | 0.46/0.39 | 0.19/0.11 | 0.61/0.48 | (0.16, |
| | | | | | | 0.09) |

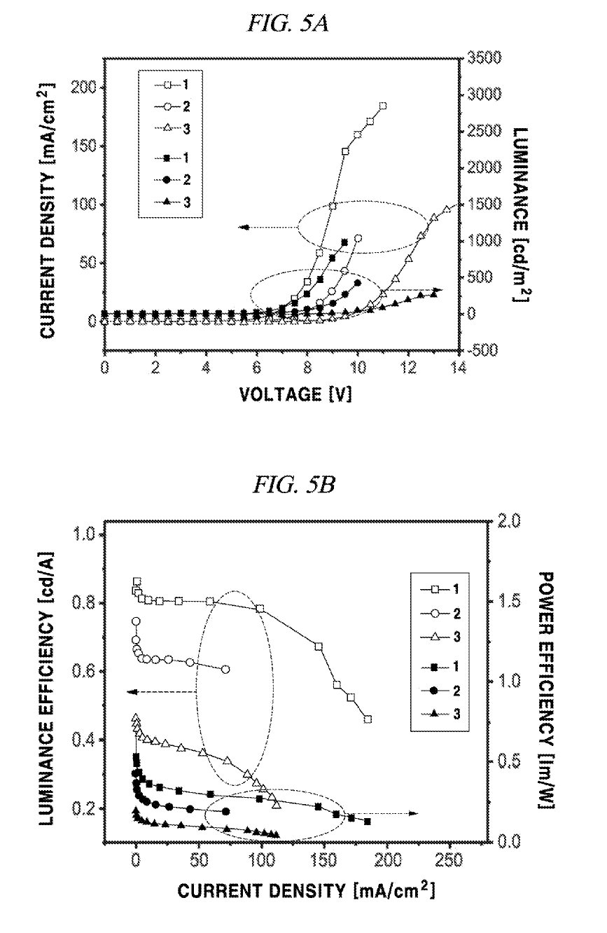

FIG. 4 illustrates normalized EL spectra of the fabricated devices 1 to 3. All devices exhibited an efficient blue emission with maximum emission peaks of from 445 nm to 462 nm, which is well compatible with the PL spectra of the materials 1 to 3. It is noted that, in comparison to the PL spectra of the materials 1 to 3, the EL spectra showed large red-shifts by around 50 nm. The differences in solvation between a solution state and a solid state device may have contributed to the large differences in the maximum peaks of PL and EL spectra. The CIExy coordinates of the devices 1 to 3 were (0.17, 0.14), (0.17, 0.17) and (0.16, 0.09), respectively, at 8.0 V. Among the devices 1 to 3, the device 3 exhibited the most pure deep blue emission with the CIExy coordinates of (0.16, 0.09), which is close to the standard deep blue emission. FIG. 5A to FIG. 5C provide graphs illustrating the current density-voltage-luminance (J-V-L) characteristics (FIG. 5A), luminance efficiency and power efficiency (FIG. 5B), and external quantum efficiency (EQE) (FIG. 5C) with respect to a current density of the devices 1 to 3.

Among the devices 1 to 3, the sky-blue device 1 exhibited outstanding EL performances with its maximum luminous, power and external quantum efficiencies of 0.86 cd/A, 0.52 lm/W, and 0.74% (0.80 cd/A, 0.34 lm/W, and 0.73% EQE at 20 mA/cm²), respectively, with CIExy coordinates of (0.17, 0.14) at 8.0 V. However, the deep-blue device 3 exhibited low EL efficiencies with a maximum luminous, power and external quantum efficiencies of 0.46 cd/A, 0.19 lm/W, and 0.61% (0.39 cd/A, 0.11 lm/W, and 0.48% EQE at 20 mA/cm²), respectively, with CIExy coordinate of (0.16, 0.09) at 8.0 V.

In comparison to material 1, the higher LUMO energy level and the lower HOMO level of material 3 suppresses the effective electron and the hole injection into the emitting layer of device 3, as compared to device 1. These ineffective carrier injection properties of device 3 may contribute to reduced EL efficiencies of device 3. Although materials 1 and 2 have the similar HOMO/LUMO energy levels and thus similar hole and electron injection properties, device 1 exhibited improved EL efficiencies in comparison to device 2. Other factors such as carrier mobility and carrier recombination factor may contribute to the differences in EL efficiencies of devices 1 and 2.

### Example 7

### Fabrication and Measurement of Devices 4 and 5

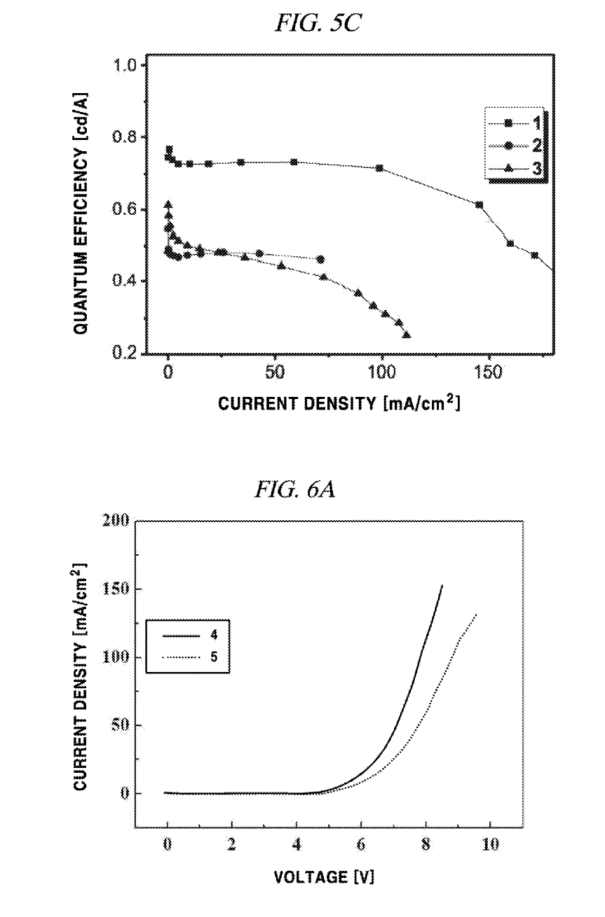

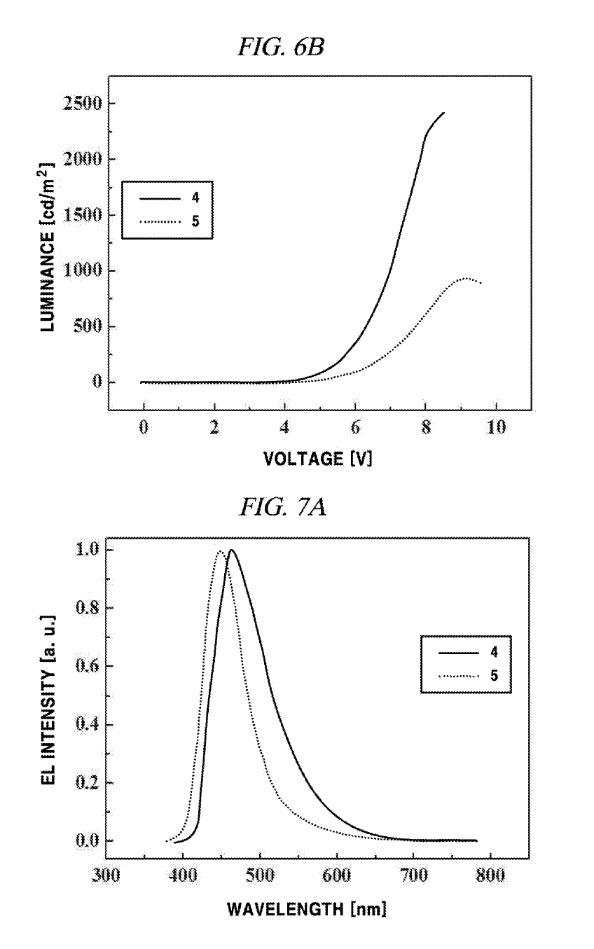

Table 3 and FIG. 6A and FIG. 6B illustrate a current density and luminance indicative of carrier injection and transport of the devices 4 and 5 depending on a voltage. The device 4 had results of 14.24 mA/cm² and 2,412 cd/m² and exhibited excellent current density and luminance as compared with the device 5.

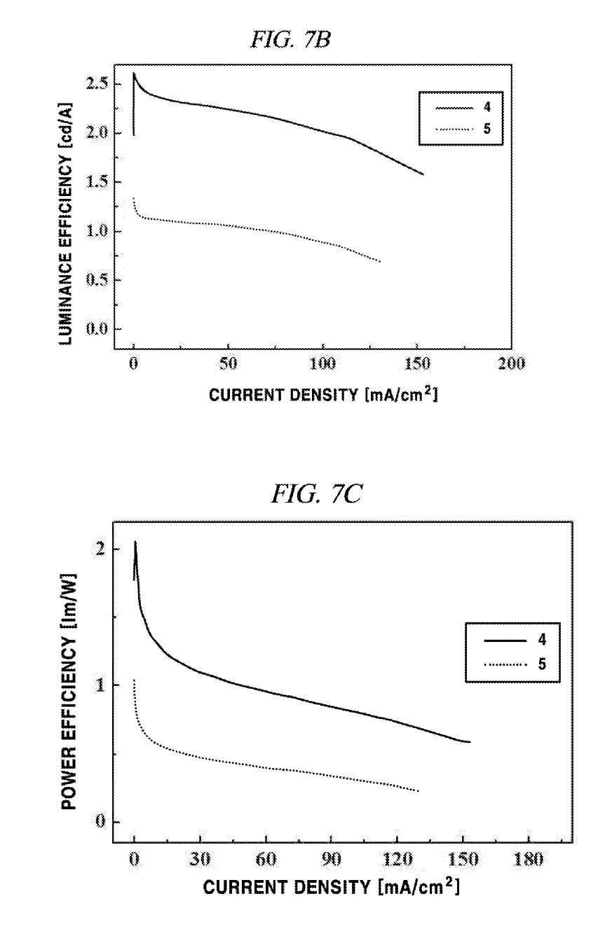

Analysis results of the devices 4 and 5 were as shown in Table 4 and FIG. 7A to FIG. 7C. FIG. 7A to FIG. 7C provide graphs respectively showing EL intensities depending on a wavelength (FIG. 7A), and luminance efficiency (LE) (FIG. 7B) and power efficiency (PE) (FIG. 7C) depending on a current density. The device 4 exhibited good efficiencies (2.34 cd/A, 1.181 m/W) at 20 mA/cm². According to the EL spectra, the device 4 exhibited emission in a range of from 462 nm to 465 nm and the device 5 exhibited emission at 448 nm, i.e. in a blue region.

TABLE 3

| | ELₘₐₓ | L | LE | PE | EQE | CIE |
|---|---|---|---|---|---|---|
| Device | [nm] | [cd/m²]^{a} | [cd/A]^{b/c} | [lm/W]^{b/c} | [%]^{b/c} | (x, y)^{d} |
| 1 | 455 | 978 | 0.86/0.80 | 0.52/0.34 | 0.74/0.73 | (0.17, |
| | | | | | | 0.14) |
| 2 | 462 | 430 | 0.75/0.63 | 0.43/0.23 | 0.55/0.48 | (0.17, |
| | | | | | | 0.17) |
| 3 | 445 | 265 | 0.46/0.39 | 0.19/0.11 | 0.61/0.48 | (0.16, |
| | | | | | | 0.09) |

TABLE 4

| Device | EL [nm] | LE^{a/b} [cd/A] | PE^{a/b} [lm/W] | CIE (x, y) |
|---|---|---|---|---|
| 4 | 462, 463, 464, 465 | 2.61/2.34 | 1.03/1.18 | (0.17, 0.23) |
| 5 | 448 | 1.31/1.11 | 2.05/0.51 | (0.16, 0.11) |

^{a}Maximum value.
^{b}At 20 mA/cm².

The fluorescent materials 1 to 5 based on triphenylene in accordance with Examples above were synthesized via Diels-Alder reaction, and an organic light emitting device (OLED) was fabricated to investigate electroluminescent properties of these materials. A device using 1,4-bis(1,4-diphenyltriphenylen-2-yl)benzene (1) as a luminescent layer exhibited the outstanding EL performance with its maximum luminous, power, and external quantum efficiencies of 0.86 cd/A, 0.52 lm/W, and 0.74% (0.80 cd/A, 0.34 lm/W, and 0.73% EQE at 20 mA/cm²), respectively, with CIExy coordinates of (0.17, 0.14) at 8.0 V. The present disclosure demonstrated that the novel organic electroluminescent compound as a triphenylene derivative is a promising blue emitting material for developing high-efficiency OLEDs.

The above description of the present disclosure is provided for the purpose of illustration, and it would be understood by those skilled in the art that various changes and modifications may be made without changing technical conception and essential features of the present disclosure. Thus, it is clear that the above-described embodiments are illustrative in all aspects and do not limit the present disclosure. For example, each component described to be of a single type can be implemented in a distributed manner. Likewise, components described to be distributed can be implemented in a combined manner.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

We claim:

1. A compound of Formula (1): 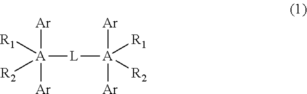
wherein A comprises a five-membered unsaturated or aromatic ring, a six-membered unsaturated or aromatic ring, a five-membered unsaturated or aromatic hetero ring, or a six-membered unsaturated or aromatic hetero ring;
either R₁ and R₂ each independently comprise a five-membered unsaturated or aromatic ring, a six-membered unsaturated or aromatic ring, a five-membered unsaturated or aromatic hetero ring, or a six-membered unsaturated or aromatic hetero ring, or
R₁ and R₂ are fused to form a polycyclic fused ring of at least two rings that are selected from the group consisting of a five-membered unsaturated or aromatic ring comprising at least one of C₆-C₂₀ fused rings, a six-membered unsaturated or aromatic ring comprising at least one of C₆-C₂₀ fused rings, a five-membered unsaturated or aromatic hetero ring comprising at least one of C₆-C₂₀ fused rings, and a six-membered unsaturated or aromatic hetero ring comprising at least one of C₆-C₂₀ fused rings;
Ar comprises a member selected from the group consisting of phenyl, biphenyl, naphthyl, dibenzothiophenyl, dibenzofuranyl, terphenyl, stilbene group, anthracenyl, pyrenyl, and perylenyl; and
L comprises a member selected from the group consisting of a five-membered unsaturated or aromatic ring that is substituted with phenyl, naphthyl, biphenyl, terphenyl, stilbene group, anthracenyl, phenanthrenyl, pyrenyl, or perylenyl; a six-membered unsaturated or aromatic ring that is substituted with phenyl, naphthyl, biphenyl, terphenyl, stilbene group, anthracenyl, phenanthrenyl, pyrenyl, or perylenyl; a five-membered unsaturated or aromatic hetero ring that is substituted with phenyl, naphthyl, biphenyl, terphenyl, stilbene group, anthracenyl, phenanthrenyl, pyrenyl, or perylenyl; and a six-membered unsaturated or aromatic hetero ring that is substituted with phenyl, naphthyl, biphenyl, terphenyl, stilbene group, anthracenyl, phenanthrenyl, pyrenyl, or perylenyl; or a polycyclic ring formed by fusion of at least two rings selected from the group consisting of a five-membered unsaturated or aromatic ring that is substituted with phenyl, naphthyl, biphenyl, terphenyl, stilbene group, anthracenyl, phenanthrenyl, pyrenyl, or perylenyl; a six-membered unsaturated or aromatic ring that is substituted with phenyl, naphthyl, biphenyl, terphenyl, stilbene group, anthracenyl, phenanthrenyl, pyrenyl, or perylenyl; a five-membered unsaturated or aromatic hetero ring that is substituted with phenyl, naphthyl, biphenyl, terphenyl, stilbene group, anthracenyl, phenanthrenyl, pyrenyl, or perylenyl; and a six-membered unsaturated or aromatic hetero ring that is substituted with phenyl, naphthyl, biphenyl, terphenyl, stilbene group, anthracenyl, phenanthrenyl, pyrenyl, or perylenyl.

2. The compound of claim 1, which is represented by one of Formulas (2), (3) and (4): 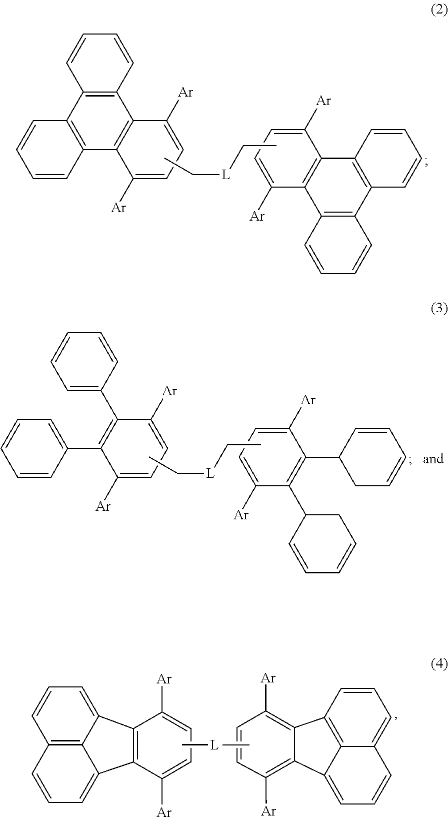
wherein Ar and L are as defined in claim 1.

3. The compound of claim 1,
wherein L is a substituent selected from the following:

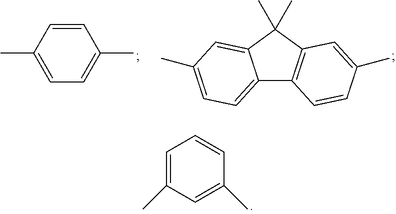

4. The compound of claim 1,
wherein the compound of Formula (1) has a maximum emission peak in a range of approximately 440 nm to 465 nm.

5. A method of producing the compound of Formula (1) according to claim 1, the method comprising:
reacting a compound represented by Formula (5) with a compound represented by Formula (6) in presence of an organic solvent: 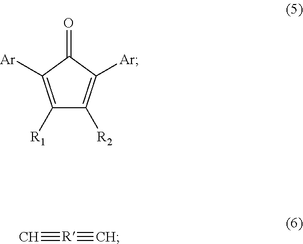
wherein
either R₁ and R₂ each independently comprise a five-membered unsaturated or aromatic ring, a six-membered unsaturated or aromatic ring, a five-membered unsaturated or aromatic hetero ring, or a six-membered unsaturated or aromatic hetero ring, or
R₁ and R₂ are fused to form a polycyclic fused ring of at least two rings that are selected from the group consisting of a five-membered unsaturated or aromatic ring comprising at least one of C₆-C₂₀ fused rings; a six-membered unsaturated or aromatic ring comprising at least one of C₆-C₂₀ fused rings; a five-membered unsaturated or aromatic hetero ring comprising at least one of C₆-C₂₀ fused rings; and a six-membered unsaturated or aromatic hetero ring comprising at least one of C₆-C₂₀ fused rings; and
Ar comprises a member selected from the group consisting of phenyl, naphthyl, biphenyl, terphenyl, stilbene group, anthracenyl, phenanthrenyl, pyrenyl, and perylenyl, and
R′ comprises a member selected from the group consisting of a five-membered unsaturated or aromatic ring that is substituted with an C₁-C₈ alkyl group; a six-membered unsaturated or aromatic ring that is substituted with an C₁-C₈ alkyl group; a five-membered unsaturated or aromatic hetero ring that is substituted with an C₁-C₈ alkyl group; and a six-membered unsaturated or aromatic hetero ring that is substituted with an C₁-C₈ alkyl group; or a polycyclic ring formed by fusion of at least two rings selected from the group above.

6. The method of claim 5,
wherein the reacting is performed at a temperature in a range of from about 100° C. to about 300° C.

7. The method of claim 5,
wherein the compound represented by Formula (5) is represented by one of Formulas (7), (8) and (9): 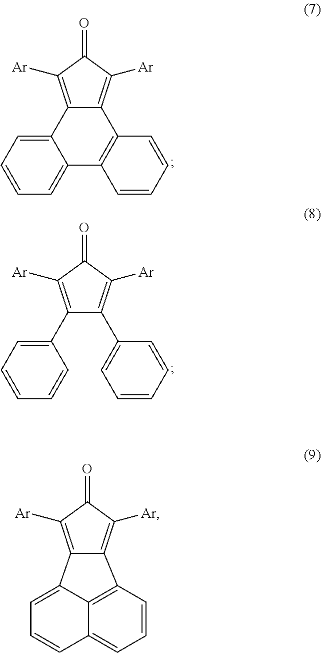
wherein Ar is the same as defined in claim 5.

8. The method of claim 5,
wherein the compound represented by Formula (6) comprises a member selected from the following:

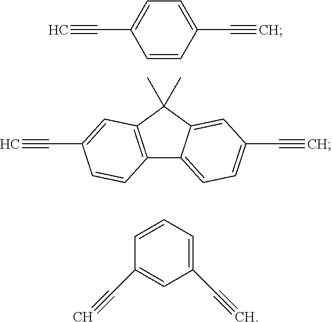

9. An organic electroluminescent diode comprising an anode, a cathode, and an organic layer comprising the compound of Formula (1) according to claim 1.
